(19) United States
(12) Patent Application Publication
(10) Pub. No.: US 2026/0020412 A1
(43) Pub. Date: Jan. 15, 2026

(54) DISPLAY APPARATUS

(71) Applicant: AUO Corporation, Hsinchu City (TW)

(72) Inventors: Ming-Lung Chen, Hsinchu City (TW); Jia Hao Hsu, Hsinchu City (TW); Kun-Cheng Tien, Hsinchu City (TW)

(73) Assignee: AUO Corporation, Hsinchu City (TW)

(21) Appl. No.: 18/974,828

(22) Filed: Dec. 10, 2024

(30) Foreign Application Priority Data
Jul. 15, 2024 (TW) 113126476
Nov. 25, 2024 (TW) 113145335

(51) Int. Cl. H10H 29/855; H10H 29/37; H10H 29/851

(52) U.S. Cl. CPC H10H 29/8552; H10H 29/37; H10H 29/8515

(57) ABSTRACT

A display apparatus including a substrate, a light-emitting device and a bank structure is provided. The light-emitting device is bonded to the substrate, and has a forward light-emitting surface, a first edge and a second edge. A length of the first edge along a first direction is greater than a length of the second edge along a second direction. The first direction and the second direction intersect each other. The bank structure has a first portion and a second portion. The first portion is disposed facing the first edge along the second direction. The second portion is disposed facing the second edge along the first direction. In a normal direction of the substrate surface, a first top surface of the first portion is lower than the forward light-emitting surface, and a second top surface of the second portion is higher than the forward light-emitting surface.

### CROSS-REFERENCE TO RELATED APPLICATION

This application claims the priority benefits of Taiwan application serial no. 113126476, filed on Jul. 15, 2024, and Taiwan application serial no. 113145335, filed on Nov. 25, 2024. The entirety of each of the above-mentioned patent applications is hereby incorporated by reference herein and made a part of this specification.

### BACKGROUND

### Technical Field

The disclosure relates to a display apparatus, and in particular, to a display apparatus provided with a light-emitting device.

### Description of Related Art

In a self-emissive display apparatus, light-emitting devices emit not only forward light but also lateral light. In order to enhance the front-view brightness of the display apparatus, in addition to improving the light emission efficiency of the light-emitting devices themselves, a concept has been proposed to guide the lateral light emitted by the light-emitting device toward a forward light-emitting surface.

For example, a lateral light-emitting surface of the light-emitting device may be covered with a bank structure with high reflectivity to reflect lateral light and increase its probability of being emitted from the forward light-emitting surface. Generally, designing the height of the bank structure to be higher than the forward light-emitting surface of the light-emitting device can maximize the reutilization of lateral light. However, the optical performance of each film layer on the bank structure is prone to degradation due to positional deviation that occur during the bonding process between the light-emitting device and a substrate.

### SUMMARY

The disclosure provides a display apparatus that balances light emission efficiency and color performance.

A display apparatus of the disclosure includes a substrate, a light-emitting device and a bank structure. The light-emitting device is bonded to the substrate, and has a forward light-emitting surface facing away from the substrate and a first edge and a second edge defining the forward light-emitting surface. The first edge and the second edge extend in a first direction and a second direction respectively. A length of the first edge along the first direction is greater than a length of the second edge along the second direction. The first direction and the second direction are parallel to a substrate surface of the substrate and intersect each other. The bank structure is disposed on the substrate, and surrounds the light-emitting device. The bank structure has a first portion and a second portion. The first portion is disposed facing the first edge of the light-emitting device along the second direction. The second portion is disposed facing the second edge of the light-emitting device along the first direction. The first portion and the second portion of the bank structure respectively have a first top surface and a second top surface facing away from the substrate. In a normal direction of the substrate surface, the first top surface is lower than the forward light-emitting surface of the light-emitting device, and the second top surface is higher than the forward light-emitting surface of the light-emitting device.

Based on the above, in a display apparatus according to an embodiment of the disclosure, the light-emitting device disposed on a substrate surface has a first edge and a second edge defining a forward light-emitting surface and intersecting each other, and a length of the first edge is greater than a length of the second edge. A bank structure surrounding the light-emitting device has a first portion and a second portion arranged respectively facing the first edge and the second edge of the light-emitting device. Since a second top surface of the second portion of the bank structure is higher than the forward light-emitting surface of the light-emitting device, the light emission efficiency of the light-emitting device may be effectively improved. On the other hand, by designing a first top surface of the first portion of the bank structure to be lower than the forward light-emitting surface of the light-emitting device, the color shift at large viewing angles caused by positional deviation during the bonding of the light-emitting device to the substrate may be significantly improved.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a schematic front view of a display apparatus according to a first embodiment of the disclosure.

FIG. 2A and FIG. 2B are enlarged schematic views of a partial area of the display apparatus of FIG. 1.

FIG. 3A and FIG. 3B are schematic cross-sectional views of the display apparatus of FIG. 2A.

FIG. 4 is an enlarged schematic view of a partial area of the display apparatus of FIG. 2A.

FIG. 5A to FIG. 5J and FIG. 6A to FIG. 6J are schematic cross-sectional views of a manufacturing process of the display apparatus of FIG. 3A and FIG. 3B.

FIG. 7 is a schematic cross-sectional view of a display apparatus according to a second embodiment of the disclosure.

FIG. 8 is a schematic cross-sectional view of a display apparatus according to a third embodiment of the disclosure.

FIG. 9 is a schematic cross-sectional view of a display apparatus according to a fourth embodiment of the disclosure.

FIG. 10 is a schematic cross-sectional view of a display apparatus according to a fifth embodiment of the disclosure.

FIG. 11 is a schematic cross-sectional view of a display apparatus according to a sixth embodiment of the disclosure.

FIG. 12 is a schematic cross-sectional view of a display apparatus according to a seventh embodiment of the disclosure.

### DESCRIPTION OF THE EMBODIMENTS

In the following detailed description of the preferred embodiments, reference is made to the accompanying drawings which form a part hereof, and in which are shown by way of illustration specific embodiments in which the invention may be practiced. In this regard, directional terminology, such as “top,” “bottom,” “front,” “back,” etc., is used with reference to the orientation of the Figure(s) being described. The components of the present invention can be positioned in a number of different orientations. As such, the directional terminology is used for purposes of illustration and is in no way limiting. On the other hand, the drawings are only schematic and the sizes of components may be exaggerated for clarity. It is to be understood that other embodiments may be utilized and structural changes may be made without departing from the scope of the present invention. Also, it is to be understood that the phraseology and terminology used herein are for the purpose of description and should not be regarded as limiting. The use of “including,” “comprising,” or “having” and variations thereof herein is meant to encompass the items listed thereafter and equivalents thereof as well as additional items. Unless limited otherwise, the terms “connected,” “coupled,” and “mounted” and variations thereof herein are used broadly and encompass direct and indirect connections, couplings, and mountings.

Similarly, the terms “facing,” “faces” and variations thereof herein are used broadly and encompass direct and indirect facing, and “adjacent to” and variations thereof herein are used broadly and encompass directly and indirectly “adjacent to”. Therefore, the description of “A” component facing “B” component herein may contain the situations that “A” component directly faces “B” component or one or more additional components are between “A” component and “B” component. Also, the description of “A” component “adjacent to” “B” component herein may contain the situations that “A” component is directly “adjacent to” “B” component or one or more additional components are between “A” component and “B” component. Accordingly, the drawings and descriptions will be regarded as illustrative in nature and not as restrictive.

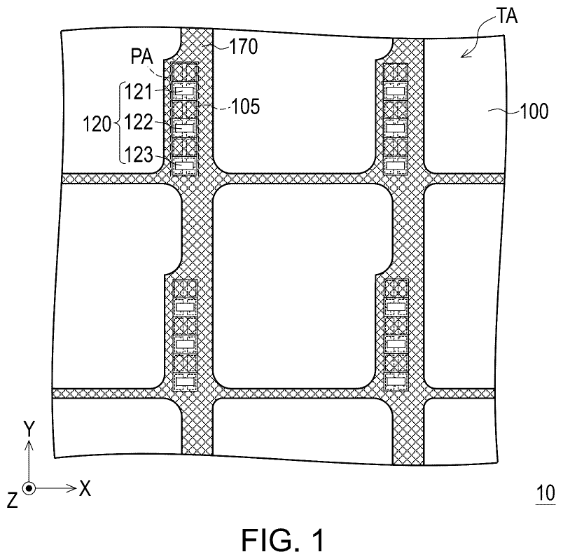

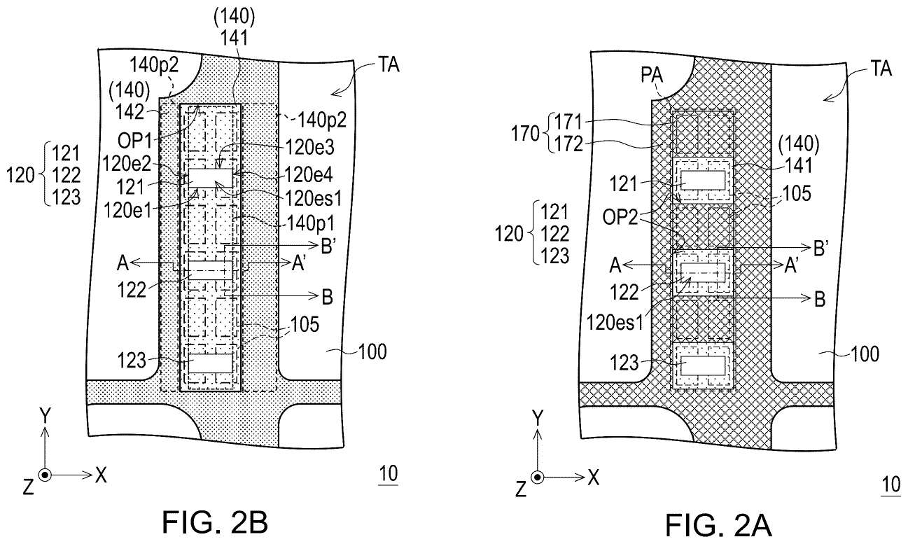

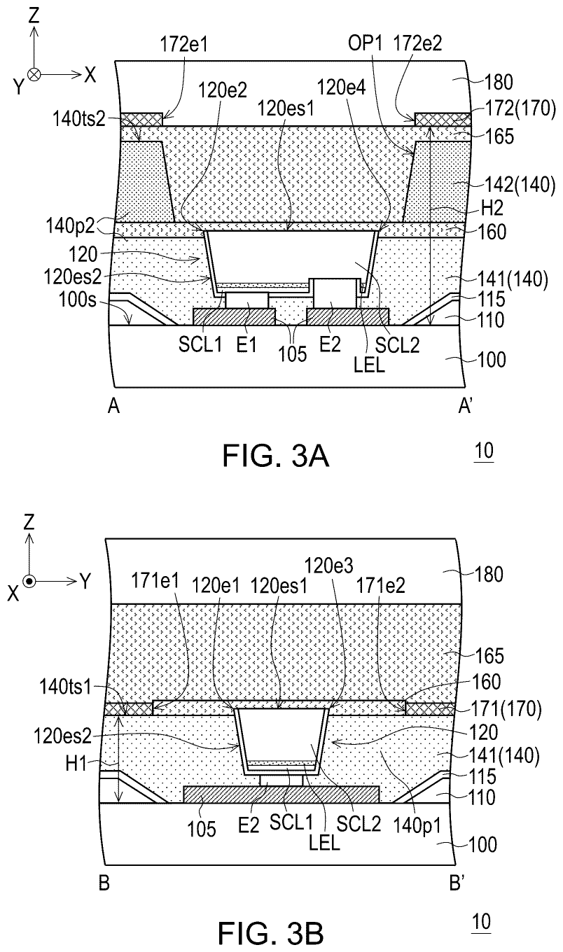

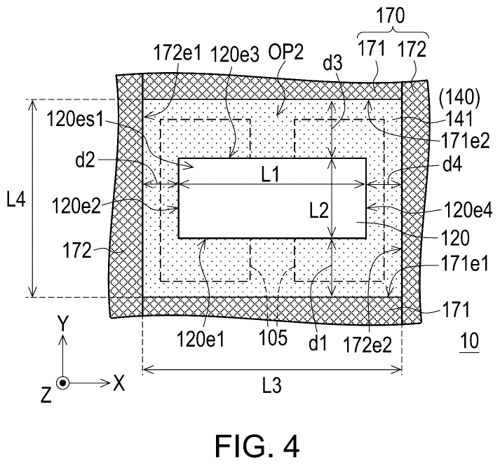

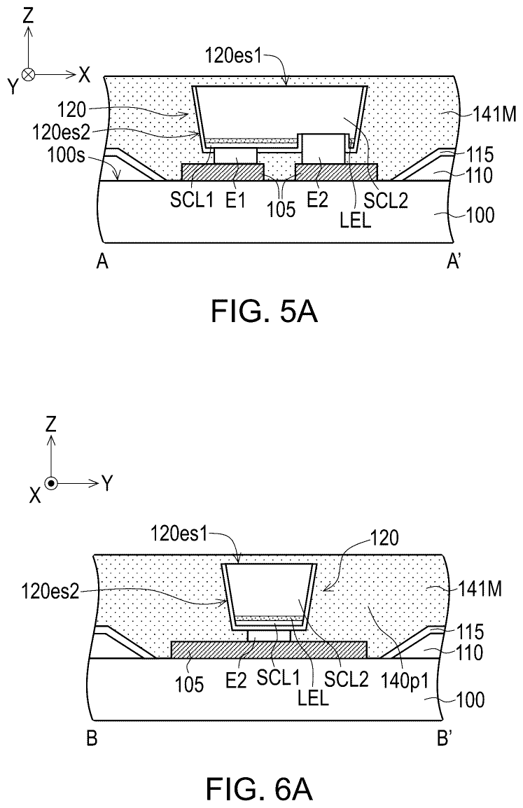

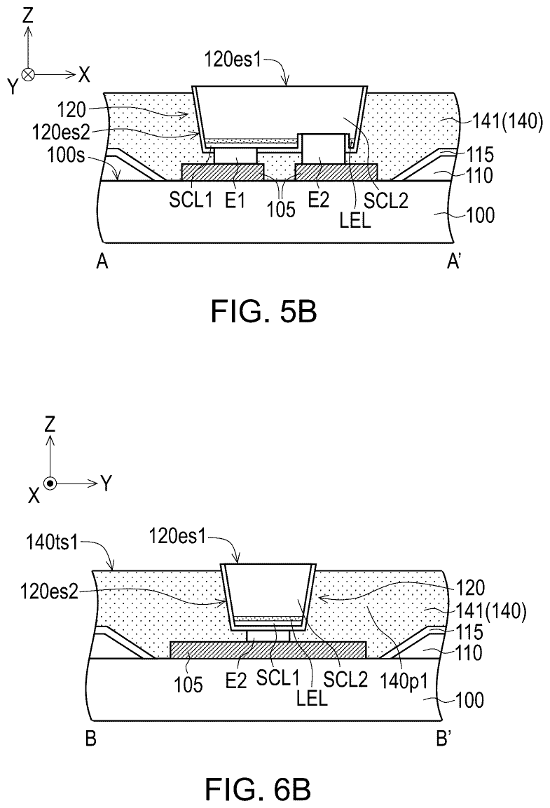

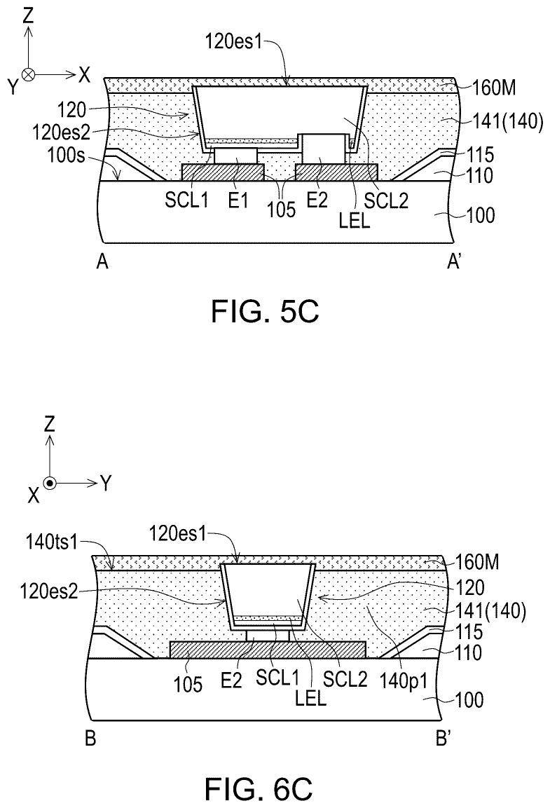

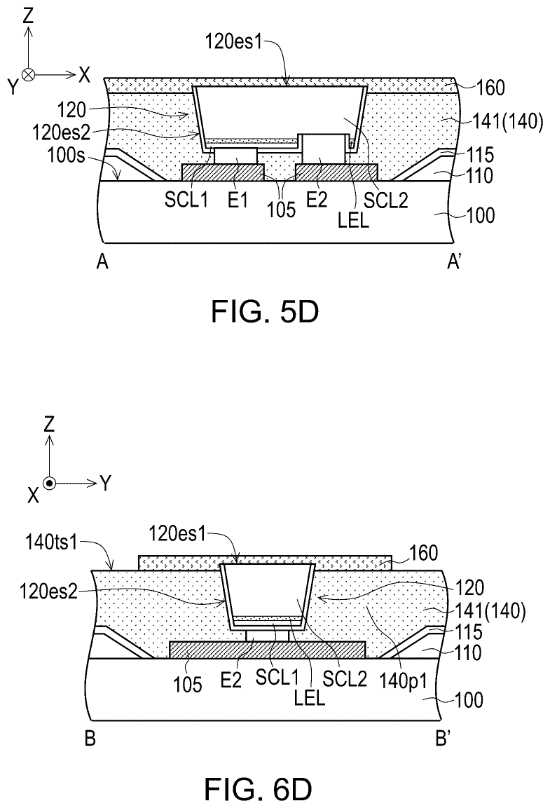

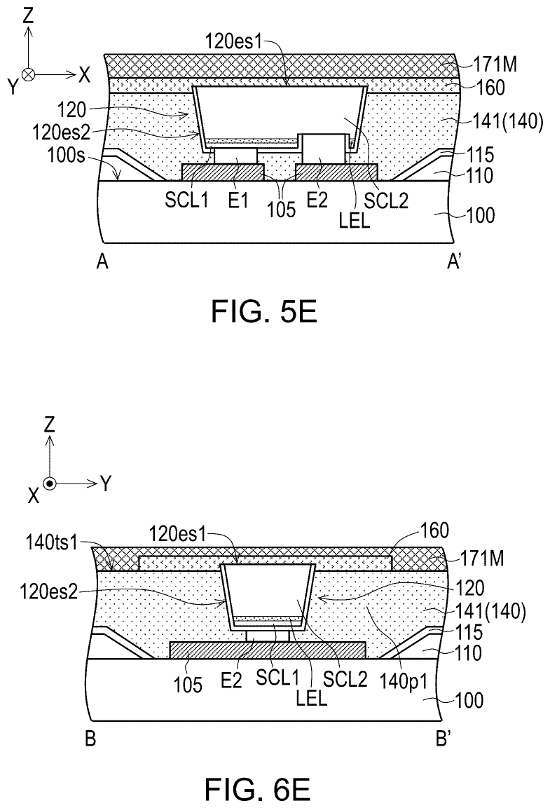

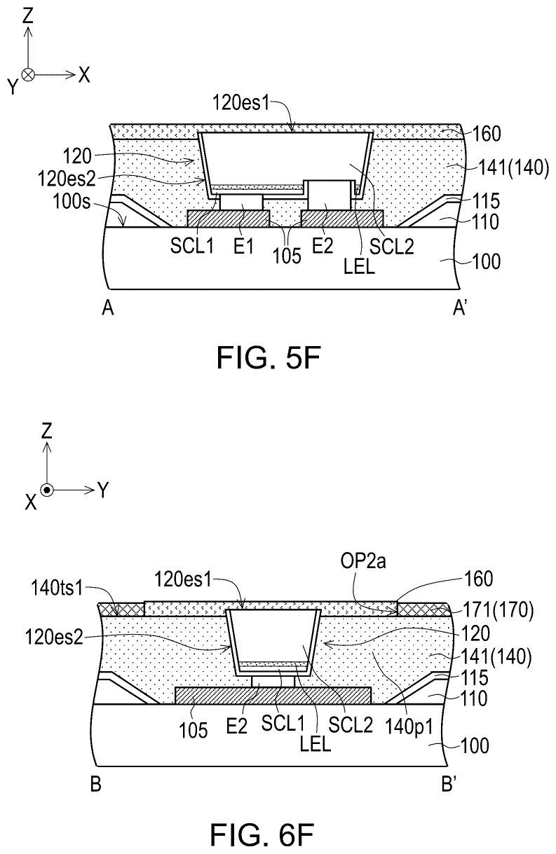

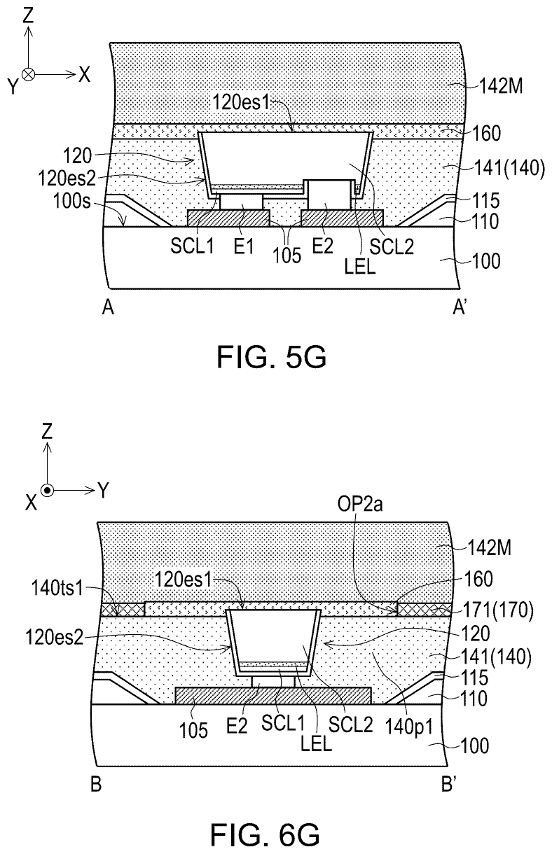

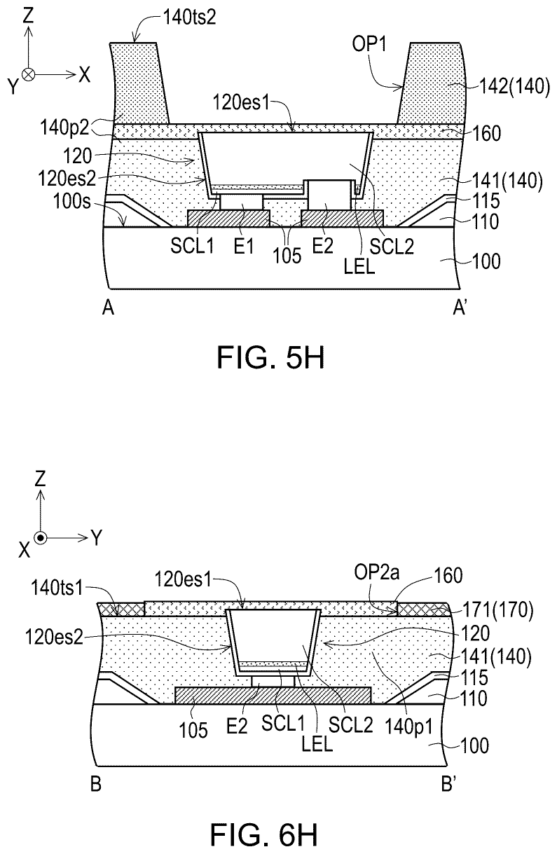

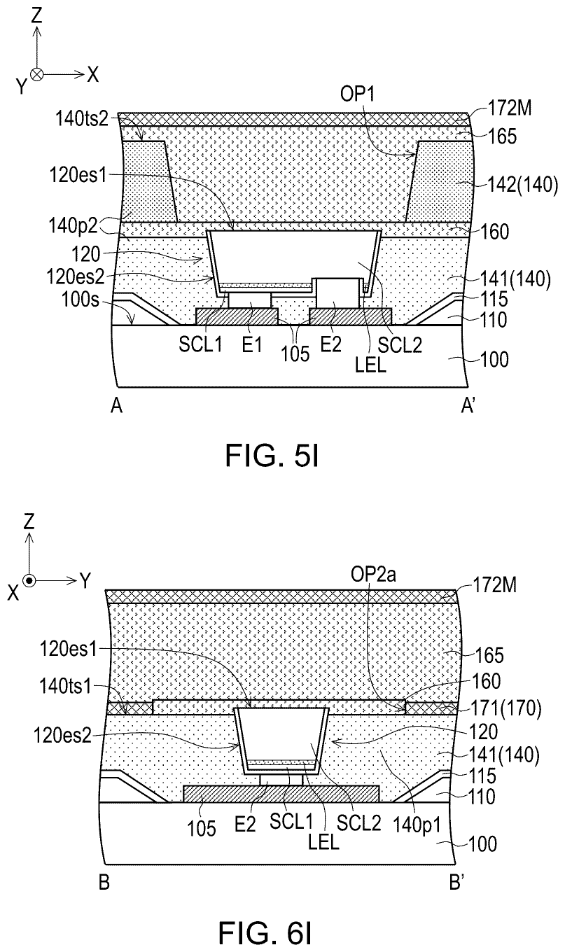

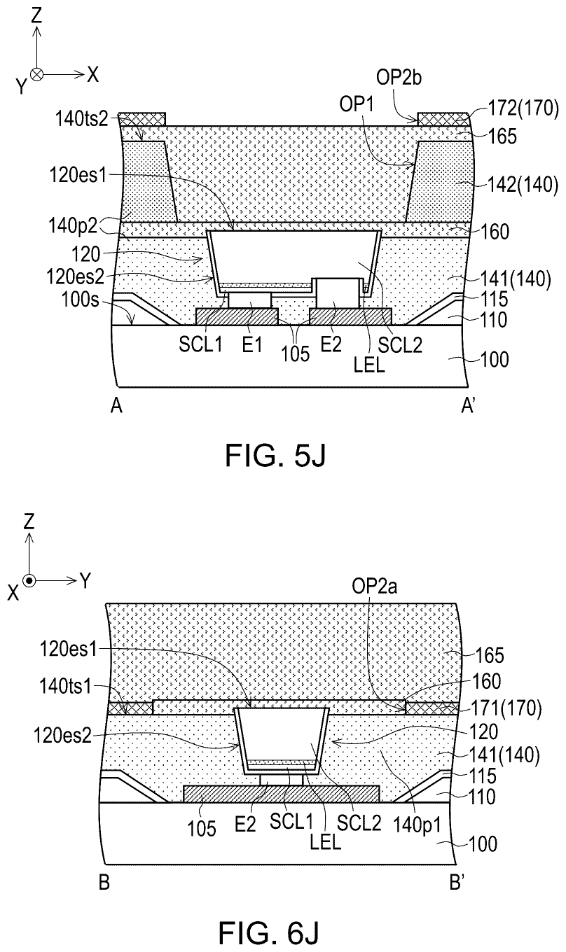

FIG. 1 is a schematic front view of a display apparatus according to a first embodiment of the disclosure. FIG. 2A and FIG. 2B are enlarged schematic views of a partial area of the display apparatus of FIG. 1. FIG. 3A and FIG. 3B are schematic cross-sectional views of the display apparatus of FIG. 2A. FIG. 4 is an enlarged schematic view of a partial area of the display apparatus of FIG. 2A. FIG. 5A to FIG. 5J and FIG. 6A to FIG. 6J are schematic cross-sectional views of a manufacturing process of the display apparatus of FIG. 3A and FIG. 3B. FIG. 3A corresponds to a cross-section line A-A′ of FIG. 2A and FIG. 2B. FIG. 3B corresponds to a cross-section line B-B′ of FIG. 2A and FIG. 2B. For clarity, FIG. 2B omits the illustration of a light-shielding structure 170 in FIG. 2A.

Referring to FIG. 1 and FIG. 2A, a display apparatus 10 includes a substrate 100 and a plurality of light-emitting devices 120. In the embodiment, the substrate 100 is, for example, a circuit board provided with a pixel circuit layer (not shown) and a plurality of bonding pads 105, and the light-emitting device 120 is adapted to be bonded to the bonding pads 105 to electrically connect to the substrate 100. The plurality of light-emitting devices 120 can be respectively bonded to a plurality of pixel areas PA on the substrate 100 and constitute a plurality of display pixels of the display apparatus 10. In the embodiment, three light-emitting devices 120 with different emission colors (e.g., red, green and blue, but the disclosure is not limited thereto), such as a light-emitting device 121, a light-emitting device 122 and a light-emitting device 123, can be bonded in each pixel area PA.

In the embodiment, the display apparatus 10 is also provided with a plurality of light-transmitting areas TA. The light-transmitting areas TA are, for example, arranged in multiple rows and columns along a direction X and a direction Y, and spaced apart from each other. The direction X intersects (e.g., is perpendicular to) the direction Y. That is, the light-transmitting areas TA can be arranged in an array on the substrate 100. It is particularly important to note that the plurality of pixel areas PA are arranged in spacing regions between the light-transmitting areas TA. In the embodiment, the aforementioned spacing regions is defined by a light-shielding structure 170 of the display apparatus 10. The light-shielding structure 170 is provided with a plurality of openings OP2 in each pixel area PA, and the openings OP2 respectively overlap the light-emitting device 121, the light-emitting device 122 and the light-emitting device 123 along a direction Z.

Referring to FIG. 2A, FIG. 3A and FIG. 3B, in the embodiment, the light-emitting device 120 may be a micro light emitting diode (micro-LED) and includes a first electrode E1, a second electrode E2 and an epitaxial structural layer. The epitaxial structure layer may include a first-type semiconductor layer SCL1, a second-type semiconductor layer SCL2, and a light-emitting layer LEL, wherein the light-emitting layer LEL is disposed between the first-type semiconductor layer SCL1 and the second-type semiconductor layer SCL2. The first electrode E1 and the second electrode E2 are electrically connected to the first-type semiconductor layer SCL1 and the second-type semiconductor layer SCL2 respectively. The first electrode E1 and the second electrode E2 of the light-emitting device 120 may be respectively bonded to two bonding pads 105 to establish an electrical connection between the light-emitting device 120 and the substrate 100.

In the embodiment, the first electrode E1 and the second electrode E2 of the light-emitting device 120 may be disposed on the same side of the epitaxial structure layer facing the substrate 100. More specifically, the light-emitting device 120 may be a flip-chip type micro-LED. In the embodiment, the light-emitting device 120 has a forward light-emitting surface 120es1 facing away from the substrate 100, a lateral light-emitting surface 120es2 connecting the forward light-emitting surface 120es1, and a first edge 120e1, a second edge 120e2, a third edge 120e3 and a fourth edge 120e4 defining the forward light-emitting surface 120es1. The lateral light-emitting surface 120es2 may surround the forward light-emitting surface 120es1. The first edge 120e1 and the third edge 120e3 extend in the direction X. The second edge 120e2 and the fourth edge 120e4 extend in the direction Y. In the embodiment, a length L1 of each of the first edge 120e1 and the third edge 120e3 along the direction X is greater than a length L2 of each of the second edge 120e2 and the fourth edge 120e4 along the direction Y (as shown in FIG. 4).

For example, the display apparatus 10 may further include a pixel defining layer 110 disposed on a substrate surface 100s of the substrate 100. The pixel defining layer 110 has a plurality of openings defining the plurality of pixel areas PA, and the openings expose the plurality of bonding pads 105 on the substrate 100.

In order to increase the light emitting intensity of the light-emitting device 120 on the forward light-emitting surface 120es1, the display apparatus 10 is further provided with a bank structure 140 on the substrate 100, and the bank structure 140 covers the lateral light-emitting surface 120es2 of the light-emitting device 120. The bank structure 140 is suitable for reflecting light emitted by the light-emitting layer LEL of the light-emitting device 120 toward the lateral light-emitting surface 120es2 back into the epitaxial structure layer, thereby increasing its probability of being emitted from the forward light-emitting surface 120es1. The material of the bank structure 140 includes, for example, white or highly reflective materials.

Referring to FIG. 2B, FIG. 3A and FIG. 3B, the bank structure 140 has an opening OP1 overlapping the light-emitting device 120 along the direction Z. For example, in the embodiment, the bank structure 140 has only one opening OP1 in each pixel area PA. The opening OP1 extends in the direction Y and overlaps the three light-emitting devices 121, 122, 123 in the pixel area PA. However, the disclosure is not limited thereto. In an unillustrated embodiment, the bank structure may have three openings respectively overlapping the three light-emitting devices 120 in each pixel area PA, and the three openings are spaced apart from each other.

In detail, the bank structure 140 includes a first bank 141 and a second bank 142. The first bank 141 is disposed on the pixel defining layer 110, and a passivation layer 115 may be provided between them. The first bank 141 is arranged around the light-emitting device 120 and covers the lateral light-emitting surface 120es2 of the light-emitting device 120. The second bank 142 is disposed on the first bank 141 and does not overlap the plurality of light-emitting devices 120 along the direction Z. More specifically, the second bank 142 is disposed on opposite sides of the light-emitting device 120 along the direction X (i.e., the first direction), but is not disposed on the opposite sides of the light-emitting device 120 along the direction Y (i.e., the second direction).

In the embodiment, a light-transmitting layer 160 is provided between the first bank 141 and the second bank 142, and the material of the light-transmitting layer 160 includes, for example, a transparent photoresist material, but the disclosure is not limited thereto. On the other hand, the second bank 142 is provided with the opening OP1 of the bank structure 140, and a scattering layer 165 may be disposed in the opening OP1. The scattering layer 165 is, for example, made from a transparent photoresist material as a base and doped with scattering particles. It should be noted that the configuration of the scattering layer 165 may further improve the color shift of the display apparatus 10 at large viewing angle caused by positional deviation during the bonding of the light-emitting device 120 to the substrate 100. However, the disclosure is not limited thereto. In other embodiments, the scattering layer 165 can be replaced by another light-transmitting layer whose material may optionally be the same as that of the light-transmitting layer 160.

From another perspective, in the embodiment, the bank structure 140 has a first portion 140p1 and a second portion 140p2. The first portion 140p1 is disposed facing the first edge 120e1 and the third edge 120e3 of the light-emitting device 120 along the direction Y. The second portion 140p2 is disposed facing the second edge 120e2 and the fourth edge 120e4 of the light-emitting device 120 along the direction X. In other words, the first portion 140p1 of the bank structure 140 is located on opposite sides of the light-emitting device 120 along the direction Y, and does not overlap the light-emitting device 120 along the direction X. The second portion 140p2 of the bank structure 140 is located on opposite sides of the light-emitting device 120 along the direction X, and does not overlap the light-emitting device 120 along the direction Y.

More specifically, a portion of the first bank 141 of the bank structure 140 overlapping the light-emitting device 120 along the direction Y constitutes the first portion 140p1 (as shown in FIG. 3B) of the bank structure 140, and a portion of the first bank 141 and the second bank 142 of the bank structure 140 overlapping the light-emitting device 120 along the direction X constitutes the second portion 140p2 (as shown in FIG. 3A) of the bank structure 140.

In the embodiment, the first portion 140p1 and the second portion 140p2 of the bank structure 140 respectively have a first top surface 140ts1 and a second top surface 140ts2 facing away from the substrate 100. The top surface of each of the aforementioned portions is, for example, the surface of each portion of the bank structure 140 that is farthest from the substrate surface 100s. That is to say, a surface of the portion of the first bank 141 that constitutes the first portion 140p1 of the bank structure 140 facing away from the substrate 100 is defined as the first top surface 140ts1, while a surface of the portion of the second bank 142 that constitutes the second portion 140p2 of the bank structure 140 facing away from the substrate 100 is defined as the second top surface 140ts2.

It is particularly important to note that, in a normal direction (e.g., the direction Z) of the substrate surface 100s, the first top surface 140ts1 of the bank structure 140 is lower than the forward light-emitting surface 120es1 of the light-emitting device 120, but higher than the light-emitting layer LEL of the light-emitting device 120. The second top surface 140ts2 of the bank structure 140 is higher than the forward light-emitting surface 120es1 of the light-emitting device 120. That is to say, a height of the second portion 140p2 of the bank structure 140 facing the second edge 120e2 and the fourth edge 120e4 of the light-emitting device 120 relative to the substrate surface 100s is higher than the forward light-emitting surface 120es1 of the light-emitting device 120 (as shown in FIG. 3A shown), and a height of the first portion 140p1 of the bank structure 140 facing the first edge 120e1 and the third edge 120e3 of the light-emitting device 120 and directly covering the lateral light-emitting surface 120es2 relative to the substrate surface 100s is lower than the forward light-emitting surface 120es1 of the light-emitting device 120 (as shown in FIG. 3B).

Referring to FIG. 3A, FIG. 3B and FIG. 4, furthermore, the light-shielding structure 170 is disposed on the bank structure 140 and includes a first light-shielding layer 171 and a second light-shielding layer 172. The first light-shielding layer 171 is disposed on the first bank 141 and overlaps the first portion 140p1 of the bank structure 140 along the direction Z. The second light-shielding layer 172 is disposed on the second bank 142 and overlaps the second portion 140p2 of the bank structure 140 along the direction Z.

In the embodiment, the first light-shielding layer 171 and the second light-shielding layer 172 respectively have a height H1 and a height H2 relative to the substrate surface 100s, and the height H2 is greater than the height H1. That is, the height H1 of the first light-shielding layer 171 disposed on the first portion 140p1 of the bank structure 140 is lower than the height H2 of the second light-shielding layer 172 disposed on the second portion 140p2 of the bank structure 140. Alternatively, the height H1 of a portion of the light-shielding structure 170 facing the first edge 120e1 and the third edge 120e3 of the light-emitting device 120 along the direction Y is lower than the height H2 of another portion of the light-shielding structure 170 facing the second edge 120e2 and the fourth edge 120e4 of the light-emitting device 120 along the direction X.

Since the display apparatus is prone to color shift at large viewing angles due to positional deviation during the bonding of the light-emitting device 120 to the substrate 100, and the length L1 of the light-emitting device 120 of the embodiment along the direction X is greater than the length L2 thereof along the direction Y, the color shift at large viewing angles caused by the positional deviation of the light-emitting device 120 in the direction Y is greater than the color shift at large viewing angles caused by the positional deviation of the light-emitting device 120 in the direction X.

Therefore, by making the second top surface 140ts2 of the second portion 140p2 of the bank structure 140 higher than the forward light-emitting surface 120es1 of the light-emitting device 120, and making the first top surface 140ts1 of the first portion 140p1 of the bank structure 140 lower than the forward light-emitting surface 120es1 of the light-emitting device 120, not only the light emission efficiency of the light-emitting device 120 may be significantly improved, but also the color shift phenomenon of the display apparatus 10 at large viewing angles caused by the positional deviation during the bonding of the light-emitting device 120 to the substrate 100 may be suppressed. That is, it can achieve a balance between the light emission efficiency and color performance of the display apparatus 10.

In the embodiment, the first light-shielding layer 171 has a light-shielding edge 171e1 and a light-shielding edge 171e2 defining the opening OP2 and extending in the direction X, while the second light-shielding layer 172 has a light-shielding edge 172e1 and a light-shielding edge 172e2 defining the opening OP2 and extending in the direction Y. It is particularly noted that a distance d1 between the light-shielding edge 171e1 and the first edge 120e1 along the direction Y and a distance d3 between the light-shielding edge 171e2 and the third edge 120e3 along the direction Y are greater than a distance d2 between the light-shielding edge 172e1 and the second edge 120e2 along the direction X and a distance d4 between the light-shielding edge 172e2 and the fourth edge 120e4 along the direction X. From another point of view, a difference between a length L4 of the opening OP2 of the light-shielding structure 170 along the direction Y and the length L2 of the light-emitting device 120 along the direction Y is greater than a difference between a length L3 of the opening OP2 of the light-shielding structure 170 along the direction X and the length L1 of the light-emitting device 120 along the direction X. Accordingly, the color shift of the display apparatus 10 at large viewing angles caused by the positional deviation during the bonding of the light-emitting device 120 to the substrate 100 may be further reduced.

In the embodiment, the display apparatus 10 may further include an encapsulation layer 180 covering the light-shielding structure 170 and the scattering layer 165. The material of the encapsulation layer 180 includes, for example, polydimethylsiloxane (PDMS).

The manufacturing method of the display apparatus 10 will be exemplarily described below.

Referring to FIG. 5A and FIG. 5B, first, performing a bonding process of a plurality of light-emitting devices 120 and a substrate 100. After completing the bonding of the light-emitting devices 120 and the substrate 100, forming a first bank material layer 141M on the substrate 100. The first bank material layer 141M covers a forward light-emitting surface 120es1 and a lateral light-emitting surface 120es2 of the light-emitting device 120, bonding pads 105 and a pixel defining layer 110.

Next, performing exposure and development processes on the first bank material layer 141M to form a first bank 141 of a bank structure 140, as shown in FIG. 5B and FIG. 6B. It should be noted that the exposure process of the first bank material layer 141M, for example, adopts a weak exposure method. Therefore, after the development process, a portion of the first bank material layer 141M above the forward light-emitting surface 120es1 of the light-emitting device 120 will be removed, leaving only a portion covering the lateral light-emitting surface 120es2.

Referring to FIG. 5C and FIG. 6C, after the first bank 141 is formed, a light-transmitting material layer 160M is formed to cover the first bank 141 and the forward light-emitting surface 120es1 of the light-emitting device 120. Exposure and development processes are performed on the light-transmitting material layer 160M to form a light-transmitting layer 160, as shown in FIG. 5D and FIG. 6D. Next, a first light-shielding material layer 171M is formed on the light-transmitting layer 160 to cover the light-transmitting layer 160 and the first bank 141, as shown in FIG. 5E and FIG. 6E.

Exposure and development processes are performed on the first light-shielding material layer 171M to form a first light-shielding layer 171, as shown in FIG. 5F and FIG. 6F. After the development process, the first light-shielding layer 171 has an opening OP2a, and the light-transmitting layer 160 is located in the opening OP2a. Referring to FIG. 5G and FIG. 6G, a second bank material layer 142M is formed on the first light-shielding layer 171. Exposure and development processes are performed on the second barrier material layer 142M to form a second bank 142 of the bank structure 140, as shown in FIG. 5H and FIG. 6H. The second bank 142 has the opening OP1 overlapping the forward light-emitting surface 120es1 of the light-emitting device 120 along the direction Z.

Referring to FIG. 5I and FIG. 6I, after the second bank 142 is formed, forming a scattering layer 165 to fill the opening OP1 of the second bank 142. Next, forming a second light-shielding material layer 172M on the scattering layer 165, and performing exposure and development processes on the second light-shielding material layer 172M to form a second light-shielding layer 172, as shown in FIG. 5J and FIG. 6J. After the development process, the second light-shielding layer 172 has an opening OP2b.

Specifically, in the normal direction of the substrate surface 100s (e.g., the direction Z), an overlapping portion of the opening OP2a of the first light-shielding layer 171 and the opening OP2b of the second light-shielding layer 172 may define the opening OP2 of the light-shielding structure 170 in FIG. 2A. Next, forming an encapsulation layer 180 on the second light-shielding layer 172 to cover the scattering layer 165 and the second light-shielding layer 172, as shown in FIG. 3A and FIG. 3B. At this point, the production of the display apparatus 10 of the embodiment is completed.

Some other embodiments are provided below to describe the invention in detail, where the same reference numerals denote the same or like components, and descriptions of the same technical contents are omitted. The aforementioned embodiment may be referred for descriptions of the omitted parts, and detailed descriptions thereof are not repeated in the following embodiment.

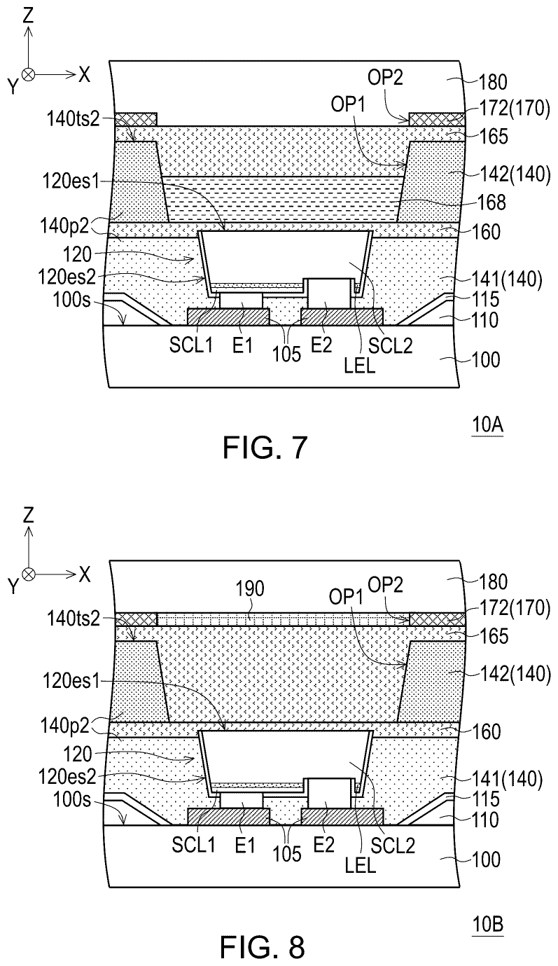

FIG. 7 is a schematic cross-sectional view of a display apparatus according to a second embodiment of the disclosure. Referring to FIG. 7, compared with the display apparatus 10 of FIG. 3A, a display apparatus 10A of the embodiment is further provided with a color conversion layer 168. For example, in the embodiment, the color conversion layer 168 may be disposed in the opening OP1 of the bank structure 140, and located between the scattering layer 165 and the light-transmitting layer 160, but the disclosure is not limited thereto. In a modified embodiment, the scattering layer 165 may be located between the color conversion layer 168 and the light-transmitting layer 160. Through the configuration of the color conversion layer 168, the flexibility in the selection of the light-emitting device 120 may be increased, and the color performance of the display apparatus 10A may be improved.

FIG. 8 is a schematic cross-sectional view of a display apparatus according to a third embodiment of the disclosure. Referring to FIG. 8, compared with the display apparatus 10 of FIG. 3A, a display apparatus 10B of the embodiment is further provided with a filter layer 190. In the embodiment, the filter layer 190 may be disposed in the opening OP2 of the light-shielding structure 170. Through the configuration of the filter layer 190, the color performance of the display apparatus 10B may be improved.

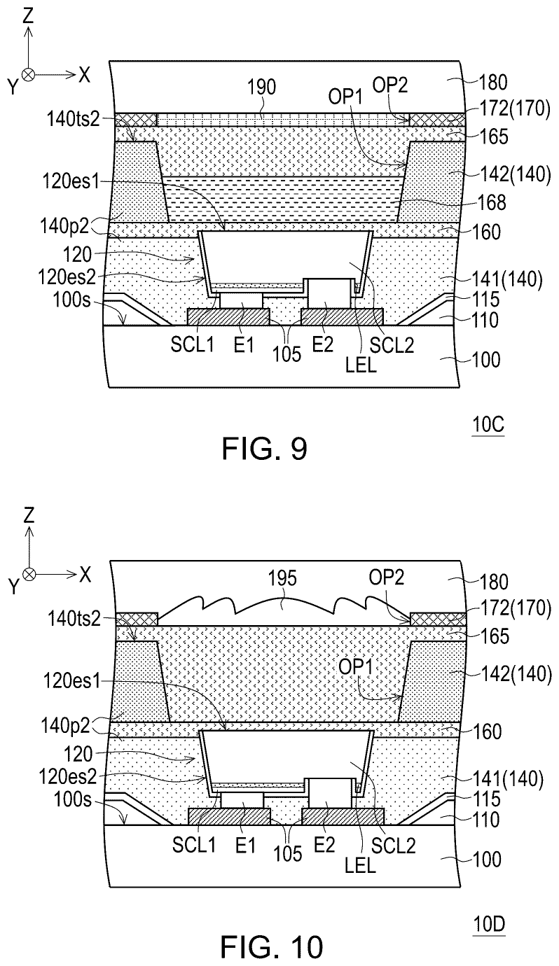

FIG. 9 is a schematic cross-sectional view of a display apparatus according to a fourth embodiment of the disclosure. Referring to FIG. 9, compared with the display apparatus 10 of FIG. 3A, a display apparatus 10C of the embodiment is further provided with a color conversion layer 168 and a filter layer 190. In the embodiment, the filter layer 190 may be disposed in the opening OP2 of the light-shielding structure 170. The color conversion layer 168 may be disposed in the opening OP1 of the bank structure 140, and is located between the scattering layer 165 and the light-transmitting layer 160, but the disclosure is not limited thereto. Through the configuration of the filter layer 190 and the color conversion layer 168, the color performance of the display apparatus 10C may be improved. In addition, the configuration of the color conversion layer 168 may also increase the flexibility in the selection of the light-emitting device 120.

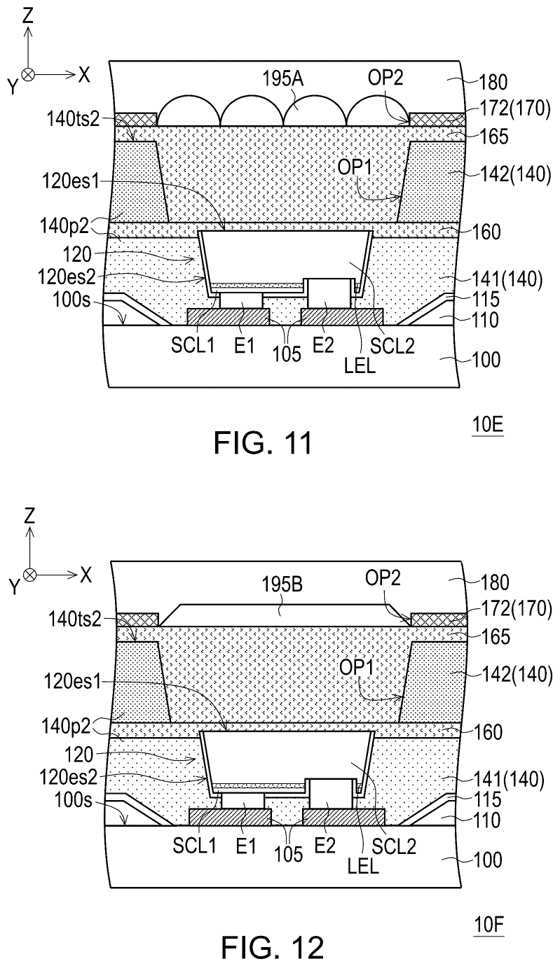

FIG. 10 is a schematic cross-sectional view of a display apparatus according to a fifth embodiment of the disclosure. FIG. 11 is a schematic cross-sectional view of a display apparatus according to a sixth embodiment of the disclosure. FIG. 12 is a schematic cross-sectional view of a display apparatus according to a seventh embodiment of the disclosure.

Referring to FIG. 10, compared with the display apparatus 10 of FIG. 3A, a display apparatus 10D of the embodiment is further provided with a lens structure 195. The lens structure 195 may be disposed in the opening OP2 of the light-shielding structure 170 and covered by an encapsulation layer 180. For example, in the embodiment, the lens structure 195 may be a Fresnel lens with characteristics such as collimation, light collection, and high gain for front-view brightness.

However, the disclosure is not limited thereto. In a display apparatus 10E of FIG. 11, the lens structure 195A may be a lens array. For example, the lens array includes a plurality of microlenses, and the microlenses may be arranged in multiple columns and rows along the direction X and the direction Y, but the disclosure is not limited thereto. In another modified embodiment of FIG. 11, the lens structure may include a plurality of micro-lenticular lenses, and the micro-lenticular lenses are arranged along the direction X and extend in the direction Y. In a display apparatus 10F of FIG. 12, the lens structure 195B may be a single lens with a flat top.

It should be noted that the lens structures in FIG. 10 to FIG. 12 are only for illustrative purposes, and the present invention is not limited by the contents disclosed in the drawings. In other embodiments, the configuration and distribution of the lens structure may be adjusted according to the actual light emission requirements of the display apparatus.

To sum up, in a display apparatus according to an embodiment of the disclosure, the light-emitting device disposed on a substrate surface has a first edge and a second edge defining a forward light-emitting surface and intersecting each other, and a length of the first edge is greater than a length of the second edge. A bank structure surrounding the light-emitting device has a first portion and a second portion arranged respectively facing the first edge and the second edge of the light-emitting device. Since a second top surface of the second portion of the bank structure is higher than the forward light-emitting surface of the light-emitting device, the light emission efficiency of the light-emitting device may be effectively improved. On the other hand, by designing a first top surface of the first portion of the bank structure to be lower than the forward light-emitting surface of the light-emitting device, the color shift at large viewing angles caused by positional deviation during the bonding of the light-emitting device to the substrate may be significantly improved.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A display apparatus, comprising:
a substrate;
a light-emitting device, bonded to the substrate, the light-emitting device has a forward light-emitting surface facing away from the substrate and a first edge and a second edge defining the forward light-emitting surface, the first edge and the second edge extend in a first direction and a second direction respectively, a length of the first edge along the first direction is greater than a length of the second edge along the second direction, and the first direction and the second direction are parallel to a substrate surface of the substrate and intersect each other; and
a bank structure, disposed on the substrate, and surrounding the light-emitting device, the bank structure has a first portion and a second portion, the first portion is disposed facing the first edge of the light-emitting device along the second direction, the second portion is disposed facing the second edge of the light-emitting device along the first direction, wherein the first portion and the second portion of the bank structure respectively have a first top surface and a second top surface facing away from the substrate, in a normal direction of the substrate surface, the first top surface is lower than the forward light-emitting surface of the light-emitting device, and the second top surface is higher than the forward light-emitting surface of the light-emitting device.

2. The display apparatus according to claim 1, further comprising:
a light-shielding structure, disposed on the bank structure, wherein the bank structure further has a first opening overlapping the light-emitting device, and the light-shielding structure has a second opening overlapping the first opening.

3. The display apparatus according to claim 2, wherein the light-shielding structure includes:
a first light-shielding layer, disposed on the first portion of the bank structure, and overlapping the first portion; and
a second light-shielding layer, disposed on the second portion of the bank structure, and overlapping the second portion, wherein the first light-shielding layer and the second light-shielding layer respectively have a first height and a second height relative to the substrate surface, and the second height is greater than the first height.

4. The display apparatus according to claim 2, wherein the light-shielding structure further has a first light-shielding edge and a second light-shielding edge defining the second opening, the first light-shielding edge and the second light-shielding edge extend in the first direction and the second direction respectively, a distance between the first light-shielding edge and the first edge along the second direction is greater than a distance between the second light-shielding edge and the second edge along the first direction.

5. The display apparatus according to claim 2, wherein the light-emitting device has a first length along the first direction and a second length along the second direction, the second opening of the light-shielding structure has a third length along the first direction and a fourth length along the second direction, the first length is greater than the second length, the third length is greater than the first length, the fourth length is greater than the second length, and a difference between the fourth length and the second length is greater than a difference between the third length and the first length.

6. The display apparatus according to claim 1, wherein the bank structure includes:
a first bank, surrounding the light-emitting device, and covering a lateral light-emitting surface, and
a second bank, disposed on the first bank, and located on opposite sides of the light-emitting device along the first direction, wherein the first bank is provided with the first top surface, the second bank is provided with the second top surface, and in the normal direction of the substrate surface, the second bank does not overlap the first top surface and the forward light-emitting surface.

7. The display apparatus according to claim 6, further comprising:
a light-transmitting layer, disposed between the first bank and the second bank.

8. The display apparatus according to claim 1, wherein the light-emitting device includes a first-type semiconductor layer, a light-emitting layer and a second-type semiconductor layer sequentially stacked on the substrate surface, the forward light-emitting surface is provided on one side of the second-type semiconductor layer facing away from the substrate, and in the normal direction of the substrate, the first top surface of the first portion of the bank structure is higher than the light-emitting layer.

9. The display apparatus according to claim 1, wherein the bank structure further has a first opening overlapping the light-emitting device, the first opening overlaps the forward light-emitting surface of the light-emitting device, and a scattering layer is provided in the first opening.

10. The display apparatus according to claim 9, wherein a color conversion layer is further provided in the first opening.

11. The display apparatus according to claim 9, further comprising:
a light-shielding structure, disposed on the bank structure, and having a second opening overlapping the first opening, wherein a light filter layer is provided in the second opening.

12. The display apparatus according to claim 9, further comprising:
a light-shielding structure, disposed on the bank structure, and having a second opening overlapping the first opening, wherein a lens structure is provided in the second opening.
